(19) United States
(12) Patent Application Publication
(10) Pub. No.: US 2025/0142725 A1
(43) Pub. Date: May 1, 2025

(54) FLEXIBLE CIRCUIT BOARD AND PAD CONNECTING SYSTEM

(71) Applicant: SUZHOU METABRAIN INTELLIGENT TECHNOLOGY CO., LTD., Jiangsu (CN)

(72) Inventor: Huali ZHOU, Jiangsu (CN)

(21) Appl. No.: 18/706,108

(22) PCT Filed: Sep. 29, 2022
(86) PCT No.: PCT/CN2022/122737

§ 371 Date: Apr. 30, 2024

(30) Foreign Application Priority Data
Mar. 31, 2022 (CN) 202210331062.5

(51) Int. Cl. H05K 1/11; H05K 1/02; H05K 3/32

(52) U.S. Cl. CPC H05K 1/118; H05K 1/0224; H05K 1/112; H05K 3/328; H05K 2201/09636; H05K 2201/09854

(57) ABSTRACT

Embodiments of the present disclosure disclose a Flexible Printed Circuit (FPC), including: a pad configured to be welded to a Printed Circuit Board (PCB), and the pad includes at least one signal pad layer and at least one ground pad layer, and a signal pad area in the at least one signal pad layer is smaller than a ground pad area in the at least one ground pad layer.

### TECHNICAL FIELD

The present disclosure relates to the technical field of circuit board design, and in particular to an FPC and a pad connection system.

### BACKGROUND

An FPC is a technology that originated in the United States in the 1970s for the development of aerospace rocket technology, and is a printed circuit made of a polyester film or polyimide as a substrate and having high reliability and excellent flexibility. By means of embedding circuit design on a bendable and thin plastic sheet, a large number of precision components are stacked and embedded in a narrow and limited space, thereby forming a bendable flexible circuit. This type of circuit may be freely bent, is light in folding weight, small in size, good in heat dissipation, and convenient to install, and breaks through the traditional interconnection technology. In the structure of the flexible circuit, the constituent materials include an insulating film, a conductor, and an adhesive.

If the characteristic impedance perceived by a signal of a Printed circuit board (PCB) maintains consistent at all times during the propagation of the signal of the PCB along a transmission line, then such a transmission line is referred to as a transmission line with controlled impedance. The instantaneous impedance or characteristic impedance of the transmission line is the most important factor affecting the signal quality. If the impedance between adjacent signal propagation intervals remains consistent during signal propagation, then the signal may propagate forward very smoothly, so that the situation becomes very simple. If there is a difference between the adjacent signal propagation intervals, or if the impedance changes, a part of the energy in the signal may be reflected back, and the continuity of signal transmission may also be disrupted. In order to ensure the best signal quality, the purpose of signal interconnection design is to ensure that the impedance perceived by the signal during transmission remains constant as much as possible, mainly to maintain the characteristic impedance of the transmission line as a constant. Therefore, it is becoming more and more important to design and manufacture a PCB with controlled impedance.

At present, the design of a common connector pad of the PCB is constrained by industry associations, the flexibility is poor, and the pad usually presents a capacitance that may pull down the impedance and lead to a problem of signal integrity.

### SUMMARY

The purpose of embodiments of the present disclosure is to provide an FPC and a pad connection system.

The embodiments of the present disclosure provide an FPC, including: a pad configured to be welded to a PCB.

The pad includes at least one signal pad layer and at least one ground pad layer. A signal pad area in the at least one signal pad layer is smaller than a ground pad area in the at least one ground pad layer.

In some embodiments, the signal pad area includes at least one first elliptical via configured for tin penetration welding of the PCB.

In some embodiments, an orthographic projection of the at least one first elliptical via on a plane parallel to the at least one signal pad layer is a line segment area formed by connecting circular endpoints with a same diameter.

In some embodiments, the ground pad area includes at least one second elliptical via configured for tin penetration welding of the PCB.

In some embodiments, an aperture size of the at least one first elliptical via is smaller than an aperture size of the at least one second elliptical via.

In some embodiments, under the condition that the signal pad area is a differential signal pad area, a size specification of the signal pad area is 0.8 mm*0.25 mm.

In some embodiments, under the condition that the signal pad area is a single-ended signal pad area, a size specification of the signal pad area is 0.9 mm*0.3 mm.

The embodiments of the present disclosure further provide a pad connection system, including: a PCB and the FPC as described above. A circuit board pad of the PCB is welded to the pad of the FPC.

In some embodiments, a circuit board signal pad area in a circuit board signal pad layer of the circuit board pad is welded to the signal pad area of the at least one signal pad layer of the pad of the FPC through a via in the at least one ground pad layer of the pad of the FPC.

In some embodiments, the circuit board pad includes at least one circuit board signal pad layer and at least one circuit board ground pad layer. A circuit board signal pad area in the at least one circuit board signal pad layer is smaller than a circuit board ground pad area in the at least one circuit board ground pad layer.

The FPC provided in the embodiment of the present disclosure includes: the pad configured to be welded to the PCB. The pad includes the at least one signal pad layer and the at least one ground pad layer. The signal pad area in the at least one signal pad layer is smaller than the ground pad area in the at least one ground pad layer.

### BRIEF DESCRIPTION OF THE DRAWINGS

In order to more clearly illustrate the embodiments of the present disclosure or the technical solutions in the related art, the drawings used in the description of the embodiments or the related art will be briefly described below. It is apparent that the drawings described below are only some embodiments of the present disclosure. Other drawings may further be obtained by those of ordinary skill in the art according to these drawings without creative efforts.

FIG. 1 is a schematic diagram of an FPC provided by one or more embodiments of the present disclosure.

FIG. 2 is a first schematic diagram of welding between another FPC and a PCB provided by one or more embodiments of the present disclosure.

FIG. 3 is a second schematic diagram of welding between another FPC and a PCB provided by one or more embodiments of the present disclosure.

FIG. 4 is a schematic diagram of a welding manner of an FPC and a PCB in a related art.

FIG. 5 is a schematic diagram of a welding manner of an FPC and a PCB provided by one or more embodiments of the present disclosure.

### DETAILED DESCRIPTION OF THE EMBODIMENTS

In order to make the purposes, technical solutions and advantages of the embodiments of the present disclosure clearer, the technical solutions in the embodiments of the present disclosure will be clearly and completely described in conjunction with the drawings in the embodiments of the present disclosure. It is apparent that the described embodiments are only a part of the embodiments of the present disclosure, and not all of them. All other embodiments obtained by those of ordinary skill in the art on the basis of the embodiments in the present disclosure without creative work shall fall within the scope of protection of the embodiments of the present disclosure.

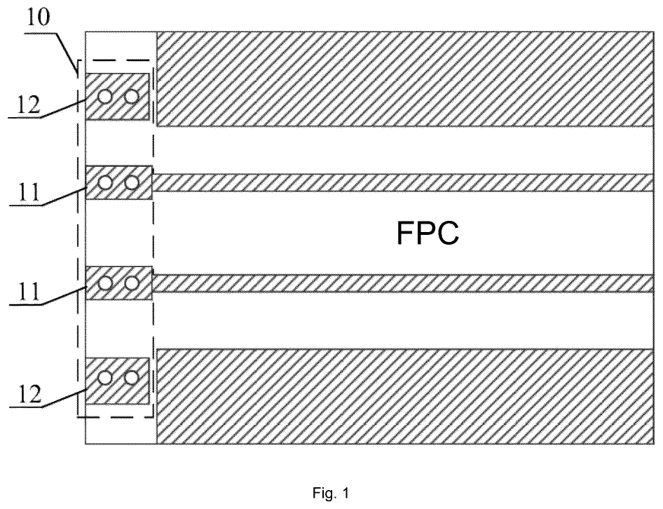

Referring to FIG. 1, FIG. 1 is a schematic diagram of an FPC provided by one or more embodiments of the present disclosure. The FPC may include: a pad 10 configured to be welded to a PCB.

The pad includes at least one signal pad layer and at least one ground pad layer. A signal pad area 11 in the at least one signal pad layer is smaller than a ground pad area 12 in the at least one ground pad layer, that is, an area of the signal pad area in the at least one signal pad layer is smaller than an area of the ground pad area in the at least one ground pad layer.

It is understandable that, the pad 10 in the FPC in the embodiment may be welded to a pad (i.e., a circuit board pad) of the PCB to implement signal transmission between the PCB and the FPC, so that the FPC may be used as a “transition bridge” for welding the PCB to another device to transmit signals between the PCB welded thereto and another device, thereby improving the welding flexibility of the PCB on the basis of ensuring the quality of communication signals between the PCB and another device. The PCB welded to the FPC in the embodiment may be a rigid PCB.

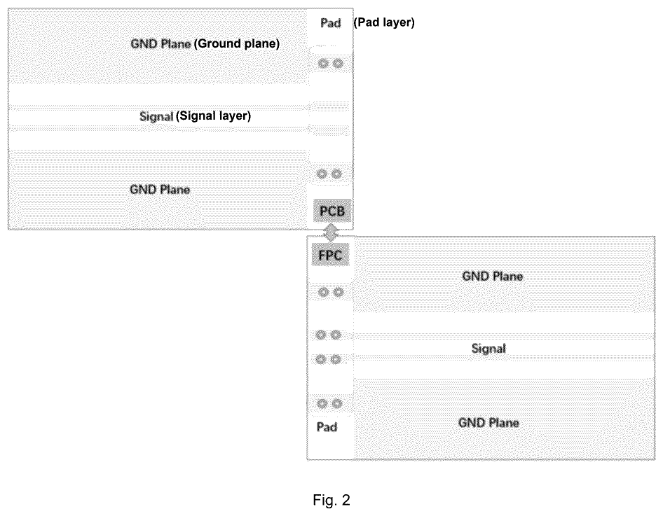

In some embodiments, the pad 10 (such as Pad of the FPC in FIG. 2) of the FPC in the embodiment may include the at least one signal pad layer corresponding to all or a part of signal layers (such as Signal (signal layer) in FIG. 2) and the at least one ground pad layer corresponding to all or a part of ground planes (such as GND Plane (ground layer) in FIG. 2). The signal pad layer may include at least one signal pad area 11 connected to the signal layer corresponding to the signal pad layer, and the ground pad layer may include at least one ground pad area 12 close to the ground plane corresponding to the ground pad layer.

Accordingly, in the embodiment, by means of adjusting the sizes of the signal pad area 11 and the ground pad area 12 in the pad 10, the impedance continuity may be optimized, thereby improving the integrity of transmission signal between the PCB and the FPC which are welded. The sizes of the signal pad area 11 and ground pad area 12 may be set by a designer according to the practical scenarios and user needs. A size of the signal pad area 11 may be adjusted according to requirements for signal impedance (such as the requirement for 100-ohm impedance of a differential signal and the requirement for 50-ohm impedance of a single-ended signal, which are common in optical communication) in combination with process production capacity, for example, in the embodiment, the signal pad area 11 may be adjusted to a minimum size acceptable for the process. Accordingly, as shown in FIG. 2, the size of the ground pad area 12 may be adjusted as much as possible, so that the ground pad area 12 may be close to the ground plane (GND Plane) corresponding to the ground pad area 12 in the FPC as much as possible, thereby reducing signal backflow paths. For example, under the condition that the signal pad area 11 is a differential signal pad area configured to transmit the differential signal, a size specification of the signal pad area 11 may be 0.8 mm*0.25 mm. Under the condition that the signal pad area 11 is a single-ended signal pad area configured to transmit the single-ended signal, a size specification of the signal pad area 11 may be 0.9 mm*0.3 mm. There are no limits made in the embodiments as long as it is ensured that the signal pad area 11 in the signal pad layer in the pad 10 may be smaller than the ground pad area 12 in the ground pad layer.

In some embodiments, sizes of a pad area (i.e., a circuit board signal pad area) in the signal pad layer (i.e., a circuit board signal pad layer) and a pad area (i.e., a circuit board ground pad area) in a ground pad layer (i.e., a circuit board ground pad layer) in the circuit board pad of the PCB welded to the FPC in the embodiment may be set in the same or similar manner as sizes arrangement of the signal pad area 11 and the ground pad area 12 in the pad 10, so that the circuit board signal pad area in the circuit board signal pad layer is smaller than the circuit board ground pad area in the circuit board ground pad layer, thereby improving the integrity of transmission signal between the PCB and the FPC which are welded, and improving the communication quality.

It is to be noted that, the signal pad area 11 and the ground pad area 12 in the embodiment may each include a via configured for tin penetration welding of the PCB. In order to improve the tin penetration yield of welding between the FPC and the PCB, in the embodiment, the via in the signal pad area 11 may be increased from a circular via in the related art to an elliptical or elliptical-like via (i.e., an elliptical via), that is, the signal pad area 11 may include at least one first elliptical via configured for tin penetration welding of the PCB. That is, an aperture size of the first elliptical via in the embodiment may be greater than an aperture size of the circular via configured for tin penetration welding of the PCB in the signal pad area 11 in the related art. For example, the first elliptical via in the embodiment may be an elliptical-like via area formed by extending from the circular via in the related art as a starting point along one side or two sides of the signal pad area by a preset distance, that is, an orthographic projection of the first elliptical via in the signal pad area 11 in the embodiment on a plane parallel to the signal pad layer corresponding to the signal pad area 11 may be a line segment area formed by connecting circular endpoints with the same diameter. The length of the line segment area corresponding to the orthographic projection of the first elliptical via on the plane parallel to the signal pad layer corresponding to the signal pad area 11 is not 0.

Accordingly, the via configured for tin penetration welding of the PCB in the signal pad area in the embodiment may also be in other shapes, for example, an orthographic projection of the via in the signal pad area on the plane parallel to the signal pad layer corresponding to the signal pad area 11 may be an area enclosed by two outer tangent lines of two circles with different diameters and the two circles. The diameter of the larger diameter of the two circles may be greater than or equal to the diameter of the circular via in the related art, so as to ensure that the aperture size of the via in the signal pad area may be greater than the circular via, thereby improving the tin penetration yield of welding between the PCB and the FPC. The shape of the via in the signal pad area is not limited in the embodiment as long as it is ensured that the aperture size of the via configured for tin penetration welding of the PCB in the signal pad area may be greater than the circular via in the related art.

In some embodiments, the via configured for tin penetration welding of the PCB in the ground pad area 12 in the embodiment may also be adjusted to an elliptical or elliptical-like via (i.e., an elliptical via), that is, the ground pad area 12 may include at least one second elliptical via configured for tin penetration welding of the PCB. That is, an aperture size of the second elliptical via in the embodiment may also be greater than an aperture size of the circular via configured for tin penetration welding of the PCB in the ground pad area 12 in the related art. For example, the fourth elliptical via in the embodiment may be an elliptical-like via area formed by extending from the circular via in the related art as a starting point along one side or two sides of the signal pad area by a preset distance, that is, an orthographic projection of the second elliptical via in the ground pad area 12 in the embodiment on a plane parallel to the ground pad layer corresponding to the ground pad area 12 may be a line segment area formed by connecting circular endpoints with the same diameter. The length of the line segment area corresponding to the orthographic projection of the second elliptical via on the plane parallel to the signal pad layer corresponding to the ground pad area 12 is not 0. As shown in FIG. 1 and FIG. 2, in the embodiment, by means of adjusting the vias in the signal pad area 11 and the ground pad area 12 in the pad 10 of the FPC from the existing conventional circular vias to the elliptical vias, the tin penetration yield of welding between the PCB and the FPC may be improved.

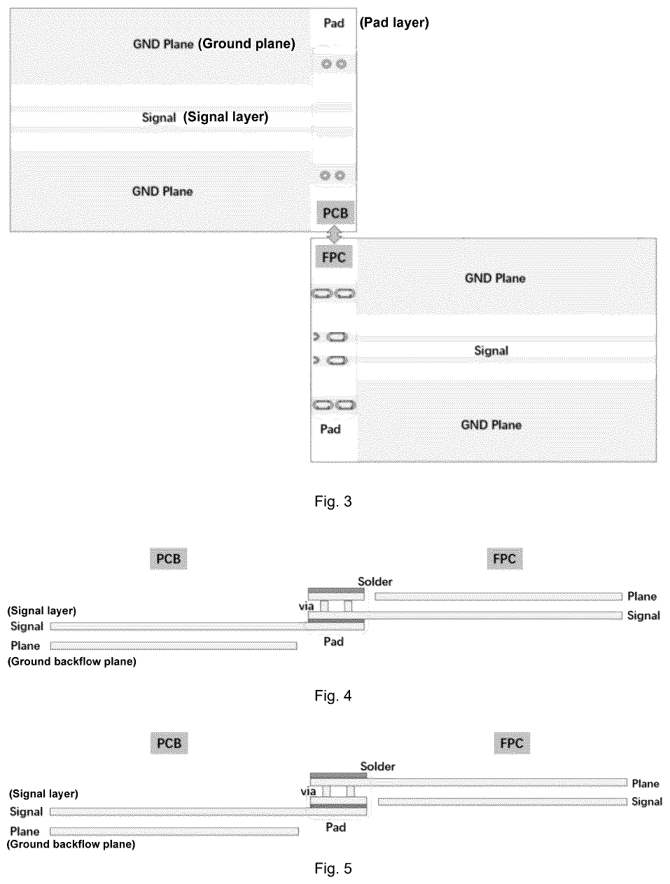

Accordingly, the aperture sizes of the vias in the signal pad area 11 and the ground pad area 12 may be set by the designer according to the scenarios and user needs. For example, the aperture sizes of the vias (such as the first elliptical vias) in the signal pad area 11 in each signal pad layer in the embodiment may be the same, that is, the aperture sizes of the vias in the signal pad area 11 in the same signal pad layer may be the same. The aperture sizes of the vias (such as the first elliptical vias) in the signal pad area 11 in all or a part of the signal pad layers may also be different, as shown in FIG. 3, the sizes of the two vias in the signal pad area 11 in the same signal pad layer may also be different, as long as it is ensured that the sum of the sizes of all the vias in the signal pad area 11 in the same signal pad layer is greater than the sum of the sizes of the circular vias provided in the related art, so that the tin penetration yield of welding between the PCB and the FPC may be improved, which is not limited in the embodiment. Similarly, the aperture sizes of the vias (such as the second elliptical vias) in the ground pad area 12 in each ground pad layer in the embodiment may be the same or different, as long as it is ensured that the sum of the aperture sizes of all the vias in the ground pad area 12 in the same ground pad layer is greater than the sum of the aperture sizes of the circular vias provided in the related art, so that the tin penetration yield of welding between the PCB and the FPC may be improved, which is also not limited in the embodiment.

Accordingly, in the embodiment, the aperture size of the via in the signal pad area 11 in each signal pad layer and the aperture size of the via in the ground pad area 12 in the ground pad layer corresponding to the signal pad layer may be the same, for example, the aperture sizes of the first elliptical via in the signal pad area 11 and the second elliptical via in the ground pad area 12 may be the same. In order to improve the tin penetration yield, since the ground pad area 12 is larger than the signal pad area 11 in the embodiment, the aperture size of the via in the ground pad area 12 may also be greater than the aperture size of the first elliptical via in the corresponding signal pad area 11.

Similarly, the number of vias in the signal pad area 11 and the number of vias in the ground pad area 12 may be set by the designer according to practical scenarios and user needs, for example, the number of vias in the signal pad area 11 in each signal pad layer in the embodiment may be the same. Accordingly, the number of vias in the ground pad area 12 in each ground pad layer may also be the same, for example, the number of second elliptical vias in the ground pad area 12 and the number of first elliptical vias in the signal pad area 11 may be the same (for example, both are 2). As long as it is ensured that the number of vias in the signal pad area 11 in each signal pad layer and the number of vias in the ground pad area 12 in the ground pad layer corresponding to the signal pad layer may be the same, that is, each via in the signal pad area 11 in each signal pad layer has a corresponding via in the ground pad area 12 in the ground pad layer corresponding to the signal pad layer, so that solder may enter the via in the signal pad area 11 from the via in the ground pad area 12 during welding, which is not limited in the embodiment.

In the embodiment of the present disclosure, by means of the optimized design of the FPC, the FPC may be used as a “transition bridge” for welding the PCB to another device, thereby improving the welding flexibility of the PCB; and by means of the arrangement in which the signal pad area 11 is smaller than the ground pad area 12 in the ground pad layer, signal backflow paths may be reduced to optimize impedance continuity, thereby improving the integrity of transmission signal.

Corresponding to the above FPC embodiment, the embodiments of the present disclosure further provide a pad connection system. The pad connection system described below and the FPC described above may be referred to each other.

The pad connection system provided in the embodiment includes: a PCB and the FPC provided in the above embodiment. A circuit board pad of the PCB is welded to the pad of the FPC.

The PCB provided in the embodiment may be a rigid PCB.

In some embodiments, the pad (i.e., the circuit board pad) of the PCB in the embodiment may be welded to the pad of the FPC to implement signal transmission between the PCB and the FPC, so that the FPC may be used as a “transition bridge” for welding the PCB to another device to transmit signals between the PCB welded thereto and another device, thereby improving the welding flexibility of the PCB.

Accordingly, the pad connection system provided in the embodiment may further include a device connected (for example, welded) to the FPC, and the device is configured to perform signal transmission with the PCB through the FPC.

It is understandable that, the circuit board pad (such as Pad of the PCB in FIG. 2) of the PCB in the embodiment may include at least one circuit board signal pad layer corresponding to all or a part of signal layers (such as Signal in FIG. 2) in the PCB and at least one circuit board ground pad layer corresponding to all or a part of ground planes (such as GND Plane in FIG. 2) of the PCB. The circuit board signal pad layer may include at least one circuit board signal pad area connected to a corresponding circuit board signal layer, and the circuit board ground pad layer may include at least one circuit board ground pad area close to the corresponding circuit board ground plane.

In some embodiments, by means of adjusting the sizes of the circuit board signal pad area and the circuit ground pad area in the circuit board pad, the integrity of transmission signal between the PCB and the FPC which are welded may be improved, for example, the sizes may be set in the same or similar manner as the size arrangement of the signal pad area and the ground pad area in the pad of the FPC in the above embodiment, so that the circuit board signal pad area in the circuit board signal pad layer is smaller than the circuit board ground pad area in the circuit board ground pad layer.

It is to be noted that, in the related art, for the sake of structural convenience, the signal layer (Signal) of the PCB and the signal layer of the FPC are usually welded in a close proximity manner through solder (such as tin) by a welding manner in which the signal layer (Signal) of the FPC is located on bottom and the ground backflow plane (Plane) of the FPC is located on top as shown in FIG. 4. However, this manner not only has the problem of signal stub (residual) at a pad welding area, but also may cause interference (such as a change in signal impedance of the FPC) to the signal backflow of the FPC due to the fact that the pad of the PCB is not designed at the board edge (such as the existence of a part of the PCB below the FPC, resulting in excess reference plane of the signal of the FPC), which ultimately triggers a series of signal quality problems, and completely ignores the signal integrity.

In the embodiment, in order to ensure the signal integrity, as shown in FIG. 5, the welding between the signal layer (Signal) of the PCB and the signal layer of the FPC is implemented by a welding manner in which the signal layer (Signal) of the FPC is on top and the ground backflow plane (Plane) is on bottom.

That is, the circuit board signal pad area in the circuit board signal pad layer of the circuit board pad in the embodiment may be welded to the signal pad area of the signal pad layer of the pad of the FPC through a via in the ground pad layer of the pad of the FPC.

Accordingly, the sizes of the circuit board signal pad area in the circuit board signal pad layer and the circuit board ground pad area in the circuit board ground pad layer in the circuit board pad of the PCB in the embodiment may be set by a designer according to the practical scenarios and user needs, for example, may be set in the same or similar manner as the size arrangement of the signal pad area and the ground pad area in the pad in the FPC. That is, the size of the circuit board signal pad area may be adjusted according to requirements for signal impedance (such as the requirement for 100-ohm impedance of a differential signal and the requirement for 50-ohm impedance of a single-ended signal, which are common in optical communication) in combination with the process production capacity, for example, in the embodiment, the circuit board signal pad area may be adjusted to a minimum size acceptable for the process. Accordingly, the size of the circuit board ground pad area may be adjusted as much as possible, so that the circuit board ground pad area may be close to the ground plane corresponding to the circuit board ground pad area in the PCB as much as possible, thereby reducing signal backflow paths. Therefore, the circuit board signal pad area in the circuit board signal pad layer may be smaller than the circuit board ground pad area in the circuit board ground pad layer, so that the integrity of transmission signal between the PCB and the FPC which are welded is improved, and the communication quality is improved.

It is to be noted that, the circuit board signal pad area and the circuit board ground pad area in the embodiment may each include at least one via configured for tin penetration welding of the FPC. In order to improve the tin penetration yield of welding between the FPC and the PCB, in the embodiment, the via in the circuit board signal pad area may be increased from a circular via in the related art to an elliptical or elliptical-like via (i.e., an elliptical via), that is, the circuit board signal pad area may include at least one third elliptical via configured for tin penetration welding of the FPC. That is, an aperture size of the third elliptical via in the embodiment may be greater than an aperture size of the circular via configured for tin penetration welding of the FPC in the circuit board signal pad area in the related art. For example, the third elliptical via in the embodiment may be an elliptical-like via area formed by extending from the circular via in the related art as a starting point along one side or two sides of the circuit board signal pad area by a preset distance, that is, an orthographic projection of the third elliptical via in the circuit board signal pad area in the embodiment on a plane parallel to the circuit board signal pad layer corresponding to the circuit board signal pad area may be a line segment area formed by connecting circular endpoints with a same diameter. The length of the line segment area corresponding to the orthographic projection of the third elliptical via on the plane parallel to the circuit board signal pad layer corresponding to the circuit board signal pad area is not 0.

Accordingly, the via configured for tin penetration welding of the PCB in the circuit board signal pad area in the embodiment may also be in other shapes, for example, the orthographic projection of the via in the circuit board signal pad area on the plane parallel to the circuit board signal pad layer corresponding to the circuit board signal pad area may be an area enclosed by two outer tangent lines of two circles of different diameters and the two circles. The diameter of the larger diameter of the two circles may be greater than or equal to the diameter of the circular via in the related art, so as to ensure that the aperture size of the via in the circuit board signal pad area may be greater than the circular via, thereby improving the tin penetration yield of welding between the PCB and the FPC. The shape of the via in the circuit board signal pad area is not limited in the embodiment as long as it is ensured that the aperture size of the via configured for tin penetration welding of the FPC in the circuit board signal pad area may be greater than the circular via in the related art.

In some embodiments, the via configured for tin penetration welding of the FPC in the circuit board ground pad area in the embodiment may also be adjusted to an elliptical or elliptical-like via (i.e., an elliptical via), that is, the circuit board ground pad area may include at least one fourth elliptical via configured for tin penetration welding of the PCB. That is, an aperture size of the fourth elliptical via in the embodiment may also be greater than an aperture size of the circular via configured for tin penetration welding of the PCB in the circuit board ground pad area in the related art. For example, the second elliptical via in the embodiment may be an elliptical-like via area formed by extending from the circular via in the related art as a starting point along one side or two sides of the signal pad area by a preset distance, that is, an orthographic projection of the fourth elliptical via in the circuit board ground pad area 1 in the embodiment on a plane parallel to the circuit board ground pad layer corresponding to the circuit board ground pad area may be a line segment area formed by connecting circular endpoints with a same diameter. The length of the line segment area corresponding to the orthographic projection of the fourth elliptical via on the plane parallel to the circuit board signal pad layer corresponding to the circuit board ground pad area is not 0. As shown in FIG. 1 and FIG. 2, in the embodiment, by means of adjusting the vias in the circuit board signal pad area and circuit board ground pad area in the circuit board pad of the PCB from the existing conventional circular vias to the elliptical vias, the tin penetration yield of welding between the PCB and the FPC may be greatly improved.

Accordingly, the aperture sizes of the vias in the circuit board signal pad area and the vias in the circuit board ground pad area may be set by the designer according to the scenarios and user needs. For example, the aperture sizes of the vias (such as the third elliptical vias) in the circuit board signal pad area in each circuit board signal pad layer in the embodiment may be the same, that is, the aperture sizes of the vias in the circuit board signal pad area in the same circuit board signal pad layer may be the same. The aperture sizes of the vias (such as the third elliptical vias) in the circuit board signal pad area in all or part of the circuit board signal pad layer may also be different, that is, the sizes of the two vias in the circuit board signal pad area in the same circuit board signal pad layer may also be different, as long as it is ensured that the sum of the sizes of all the vias in the circuit board signal pad area in the same circuit board signal pad layer is greater than the sum of the sizes of the circular vias provided in the related art, so that the tin penetration yield of welding between the PCB and the FPC may be improved, which is not limited in the embodiment. Similarly, the aperture sizes of the vias (such as the fourth elliptical vias) in the circuit board ground pad area in each circuit board ground pad layer in the embodiment may be the same or different, as long as it is ensured that the sum of the aperture sizes of all the vias in the circuit board ground pad area in the same circuit board ground pad layer is greater than the sum of the aperture sizes of the circular vias provided in the related art, so that the tin penetration yield of welding between the PCB and the FPC may be improved, which is also not limited in the embodiment.

Accordingly, in the embodiment, the aperture size of the via in the circuit board signal pad area in each circuit board signal pad layer and the aperture size of the via in the circuit board ground pad area in the circuit board ground pad layer corresponding to the circuit board signal pad layer may be the same, for example, the aperture sizes of the third elliptical via in the circuit board signal pad area and the fourth elliptical via in the circuit board ground pad area may be the same. In order to improve the tin penetration yield, since the circuit board ground pad area is larger than the circuit board signal pad area in the embodiment, the aperture size of the via in the circuit board ground pad area may also be greater than the aperture size of the third elliptical via in the circuit board signal pad area corresponding to the circuit board ground pad area.

Similarly, the number of vias in the circuit board signal pad area and the number of vias in the circuit board ground pad area may be set by the designer according to practical scenarios and user needs, for example, the number of vias in the circuit board signal pad area in each circuit board signal pad layer in the embodiment may be the same. Accordingly, the number of vias in the circuit board ground pad area in each circuit board ground pad layer may also be the same, for example, the number of fourth elliptical vias in the circuit board ground pad area and the number of third elliptical vias in the circuit board signal pad area may be the same (for example, both are 2). As long as it is ensured that the number of vias in the circuit board signal pad area in each circuit board signal pad layer and the number of vias in the circuit board ground pad area in the circuit board ground pad layer corresponding to the circuit board signal pad layer may be the same, that is, each via in the circuit board signal pad area in each circuit board signal pad layer has a corresponding via in the circuit board ground pad area in the circuit board ground pad layer corresponding to the circuit board signal pad layer, so that solder may enter the via in the circuit board signal pad area corresponding to the circuit board ground pad area from the via in the circuit board ground pad area during welding, which is not limited in the embodiment.

In the embodiment of the present disclosure, by means of the optimized design of the FPC welded to the PCB in the pad connection system, the FPC may be used as a “transition bridge” for welding the PCB to another device, thereby improving the welding flexibility of the PCB; and the signal pad area in the FPC is smaller than the ground pad area in the ground pad layer, signal backflow paths may be reduced to optimize impedance continuity, thereby improving the integrity of transmission signal between the PCB and the FPC.

The various embodiments in the present specification are described in a progressive manner, and each embodiment focuses on differences from other embodiments, and the same similar parts between the various embodiments may be referred to each other. For the system disclosed in the embodiment, since it corresponds to the FPC disclosed in the embodiment, the description is relatively simple, and the relevant parts may be referred to the method part.

It can be seen that, in the embodiments of the present disclosure, by means of the optimized design of the FPC, the FPC may be used as a “transition bridge” for welding the PCB to another device, thereby improving the welding flexibility of the PCB; and by means of the arrangement in which the signal pad area is smaller than the ground pad area in the ground pad layer, signal backflow paths may be reduced to optimize impedance continuity, thereby improving the integrity of transmission signal. In addition, the embodiments of the present disclosure further disclose the pad connection system with the same beneficial effects mentioned above.

The FPC and the pad connection system provided in the embodiments of the present disclosure are described in detail above. The principles and implementations of the embodiments of the present disclosure are described herein using optional examples, the foregoing description of the embodiments are only used to help the understanding of the method and core concept of the embodiments of the present disclosure. It is to be noted that a number of variations and modifications may be made by those of ordinary skill in the art without departing from the principle of the embodiments of the present disclosure, and all fall within the scope of protection of the claims of the embodiments of the present disclosure.

1. A Flexible Printed Circuit (FPC), comprising: a pad configured to be welded to a Printed Circuit Board (PCB);
wherein the pad comprises at least one signal pad layer and at least one ground pad layer:
and a signal pad area in the signal pad layer is smaller than a ground pad area in the ground pad layer.

2. The FPC as claimed in claim 1, wherein the signal pad area comprises at least one first elliptical via configured for tin penetration welding of the PCB.

3. The FPC as claimed in claim 2, wherein an orthographic projection of the first elliptical via on a plane parallel to the signal pad layer is a line segment area formed by connecting circular endpoints with a same diameter.

4. The FPC as claimed in claim 2, wherein the ground pad area comprises at least one second elliptical via configured for tin penetration welding of the PCB.

5. The FPC as claimed in claim 4, wherein an aperture size of the first elliptical via is smaller than an aperture size of the second elliptical via.

6. The FPC as claimed in claim 4, wherein an orthographic projection of the second elliptical via on a plane parallel to the ground pad layer is a line segment area formed by connecting circular endpoints with a same diameter.

7. The FPC as claimed in claim 1, wherein under the condition that the signal pad area is a differential signal pad area, a size specification of the signal pad area is 0.8 mm*0.25 mm.

8. The FPC as claimed in claim 1, wherein under the condition that the signal pad area is a single-ended signal pad area, a size specification of the signal pad area is 0.9 mm*0.3 mm.

9. The FPC as claimed in claim 1, wherein the pad comprises the signal pad layer corresponding to all or a part of signal layers in the FPC, and the ground pad layer corresponding to all or a part of ground planes of the FPC.

10. The FPC as claimed in claim 1, wherein a size of the signal pad area is obtained according to requirements for signal impedance in combination with process production capacity.

11. The FPC as claimed in claim 1, wherein an orthographic projection of a via configured for tin penetration welding of the PCB in the signal pad area on a plane parallel to the signal pad layer corresponding to the signal pad area is an area enclosed by two outer tangent lines of two circles with different diameters and the two circles.

12. The FPC as claimed in claim 1, wherein each via in the signal pad area in each signal pad layer corresponds to a via in the ground pad area in the ground pad layer corresponding to the signal pad layer, so that solder enters the via in the signal pad area from the via in the ground pad area during welding.

13. The FPC as claimed in claim 1, wherein an aperture size of a via in the signal pad area in each signal pad layer is the same as an aperture size of a via in the ground pad area in the ground pad layer corresponding to the signal pad layer.

14. The FPC as claimed in claim 2, wherein an aperture size of a via in the ground pad area is greater than an aperture size of the first elliptical via in the signal pad area corresponding to the ground pad area.

15. A pad connection system, comprising: a Printed Circuit Board (PCB) and a Flexible Printed Circuit (FPC), wherein the FPC comprises a pad configured to be welded to the PCB, the pad comprises at least one signal pad layer and at least one ground pad layer, and a signal pad area in the signal pad layer is smaller than a ground pad area in the ground pad layer, a circuit board pad of the PCB is welded to the pad of the FPC.

16. The pad connection system as claimed in claim 15, wherein a circuit board signal pad area in a circuit board signal pad layer of the circuit board pad is welded to the signal pad area of the signal pad layer of the pad of the FPC through a via in the ground pad layer of the pad of the FPC.

17. The pad connection system as claimed in claim 15, wherein the circuit board pad comprises at least one circuit board signal pad layer and at least one circuit board ground pad layer, wherein a circuit board signal pad area in the circuit board signal pad layer is smaller than a circuit board ground pad area in the circuit board ground pad layer.

18. The pad connection system as claimed in claim 15, wherein the circuit board pad of the PCB comprises at least one circuit board signal pad layer corresponding to all or a part of signal layers in the PCB, and at least one circuit board ground pad layer corresponding to all or a part of ground planes of the PCB.

19. The pad connection system as claimed in claim 15, wherein the PCB and the FPC are welded in a manner in which a signal layer of the FPC is on top and a ground plane of the FPC is on bottom.

20. The pad connection system as claimed in claim 15, wherein sizes of a circuit board signal pad area in a circuit board signal pad layer and a circuit board ground pad area in a circuit board ground pad layer in the circuit board pad of the PCB are set in the same manner as sizes arrangement of the signal pad area and the ground pad area in the pad of the FPC.
